(19) United States
(12) Patent Application Publication
(10) Pub. No.: US 2009/0014860 A1
(43) Pub. Date: Jan. 15, 2009

(54) Multi-chip stack structure and fabricating method thereof

(75) Inventors: Chung-Lun Liu, Taichung Hsien (TW); Jung-Pin Huang, Taichung Hsien (TW); Chin-Huang Chang, Taichung Hsien (TW); Chih-Ming Huang, Hsinchu Hsien (TW); Cheng-Hsu Hsiao, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/011,832

(22) Filed: Jan. 29, 2008

(30) Foreign Application Priority Data
Jul. 13, 2007 (TW) 096125512

(51) Int. Cl. H01L 21/00; H01L 23/02

(52) U.S. Cl. 257/686; 438/109; 257/E23.085

(57) ABSTRACT

A multi-chip stack structure and a manufacturing method thereof are provided. The fabrication method includes the steps of: providing a chip carrier having a first surface and a second surface opposing thereto and at least a first chip and a second chip mounted on the first surface; electrically connecting the chips to the chip carrier by a plurality of bonding wires; and stacking at least a third chip on the first and second chips by a film deposed therebetween, wherein the third chip is stepwise stacked on the first chip and at least a part of the bonding wire connected to the second chip is covered by the film, and electrically connecting the third chip and the chip carrier by a bonding wire, thereby enabling a plurality of chips to be stacked on the chip carrier to enhance the electrical performance of electronic products.

### FIELD OF THE INVENTION

This invention relates to a semiconductor structure and a fabricating method thereof, and more particularly, to a multi-chip stack structure and a fabrication method thereof.

### BACKGROUND OF THE INVENTION

Since in the electronics industry, greater and greater numbers of semiconductor devices on a single integrated circuit is desirable, manufacturers seek better methods to minimize the devices by reducing device geometries or the size of features. One way to produce increasingly complex electronic components is to include a greater number of IC chips on a substrate. However, such chips can take up a lot of substrate surface area. One solution to this dilemma is to stack chips on a substrate, creating what is known in the art as a multi-chip package (Multichip Module).

An ongoing demand for miniaturization of electronic products with high-speed operation often requires using packages that incorporate two or more semiconductor chips in one single package structure, thereby reducing the overall size while increasing the functionality and/or electrical performance of the package. Moreover, a stacked multi-chip structure can reduce the length of the connecting wires between chips to reduce signal delays and access times.

The often-seen multi-chip package structures typically employ a side-by-side configuration, i.e. by aligning two or more chips side by side on a major installation surface of a common substrate. The connection of conductive circuits between the chips and the common substrate is achieved by a wire bonding method. However, this side-by-side multi-chip configuration has some distinct disadvantages in that it requires high packaging cost and also takes up a relatively large amount of space within the package as well as on the common substrate due to the increased number of chips.

To overcome the problems of the prior art as mentioned above, a common method used in recent years is to stack multiple chips in varied ways according to the chip design and the wire bonding method. For example, a memory card structure is a circuit module incorporating a plurality of high-capacity chips, in which the flash memory chips thereof are formed by configuring bonding pads on the surface of only one side of the chip, such that the chips can be stacked in a stepwise fashion, thereby allowing the stacked chips to expose the bonding pads configured on one side for a subsequent wire bonding method.

Referring to FIG. 1A and FIG. 1B, a multi-chip stack structure disclosed by U.S. Pat. No. 6,538,331 is illustrated, characterized in that a plurality of flash memory chips are stacked one on another on a chip carrier 10, wherein a first flash memory chip 11 is mounted on the chip carrier 10, and a second flash memory chip 12 is stacked on the first chip 11 at an offset distance to avoid interfering with the wire bonding method for the bonding pads of the first flash memory chip 11, thus forming a stepwise multi-chip stack structure. Moreover, a controller 13 having a plurality of bonding pads formed on the periphery thereof is further provided in the memory card of an electronic device, thereby allowing the flash memory chips 11, 12 and the controller 13 to be electrically connected to the chip carrier 10 by a plurality of bonding wires 15 in a wire bonding method.

While stacking the controller 13 on the second memory chip 12 in vertical configuration can save space than aligning the chips side-by-side, it inevitably increases the height of the overall package structure by the stacked configuration. Moreover, the planar size of the general controller 13 is typically much smaller than that of the memory chips 11, 12, such that when the control chip 13 is electrically connected to chip carrier 10 by the bonding wires 15, those bonding wires 15 must pass over the memory chips 11, 12 located under the controller 13 that may easily cause short circuits due to the contact of the bonding wires 15 with the chips 11, 12 and further increase difficulties in wire bonding method.

On the other hand, it takes up more space on the chip carrier if the controller 13 is deposed thereon at areas clear of memory chips 11, 12, thus going against the increasing demand for miniaturization of electronic products.

As such, what is needed in the art is to provide an optimized multi-chip stack structure and a fabricating thereof that is capable of integrating multiple chips within one single package structure yet without increasing the size and height thereof to meet the demand of miniaturization, and further facilitating the wire bonding method and preventing the short circuit problem from occurrence.

### SUMMARY OF THE INVENTION

In light of the aforesaid drawbacks of the prior art, it is a primary objective of the present invention to provide a multi-chip stack structure and a method of fabricating the same to stack stepwise a maximum number of chips on a single package structure without occupying extra layout space thereof.

Another objective of the present invention is to provide a multi-chip stack structure and a fabricating thereof that is applicable for use in electronic apparatuses having a thinned profile and miniaturized structure.

Another objective of the present invention is to provide a multi-chip stack structure and a fabricating method thereof that can facilitates the wire bonding method and further prevent short circuits from occurring due to the contact of wires with the chip.

In order to achieve the above and other objectives, the present invention discloses a fabricating method of a multi-chip stack structure comprising the steps of: providing a chip carrier having a first surface and a second surface opposing thereto and at least a first chip and a second chip deposed on the first surface, wherein the first and second chips are electrically connected with the chip carrier by a plurality of bonding wires; stacking at least a third chip on the first and second chips by a film deposed therebetween, wherein the third chip is stacked stepwise on the first chip, and a part of the bonding wire connected to the second chip is covered by the film; and electrically connecting the third chip and the chip carrier by another bonding wire.

By the fabrication method described above, the present invention further discloses a multi-chip stack structure, comprising: a chip carrier having a first surface and a second surface opposing thereto; at least one first chip mounted on the first surface of the chip carrier and electrically connected to the chip carrier by a first bonding wire; at least one second chip mounted on the first surface of the chip carrier and electrically connected to the chip carrier by a second bonding wire; and at least one third chip stacked on the first and second chips by a film deposed therebetween and electrically connected to the chip carrier by a third bonding wire, wherein at least a part of the second bonding wire connected to the second chip is covered by the film and the third chip is stepwise stacked on the first chip.

In addition, the third chip may have a fourth chip stacked stepwise thereon. Further, the chips can be electrically connected to the chip carrier by a common wire bonding method or a reverse wire bond method. The reverse wired bond technique is characterized by bonding the outer end of the wire to the chip carrier and then bonding the inner end of the wire to the chip so as to reduce the height of the loop and the thickness of the film, thereby providing an as thinner as possible multi-chip stack structure for use with miniaturized electronic products.

Each of the first, third and fourth chips has a plurality of bonding pads formed on a single edge of a surface thereof (such as a memory chip). The third and fourth chips are stacked on the respective lower chips thereof (i.e. the first and the third chips respectively) with each of the edges provided with bonding pads thereof being deviated from that of the lower ones a predetermined distance, thus the chips are stepwise stacked. The second chip has a plurality of bonding pads formed on at least an edge of a surface thereof (such as a control chip), and the planar size of the second chip is smaller than that of the first, third or fourth chips.

In summary, the multi-chip stack structure and the fabrication method thereof according to the present invention are characterized by mounting at least a first and a second chips on the surface of the chip carrier, electrically connecting the first and second chips to the chip carrier by a plurality of bonding wires; stacking the third chip stepwise on the first and second chips by a Film over Wire (FOW technique), wherein the third chip is stepwise stacked on the first chip, and at least a part of the bonding wire connected to the second chip is covered by the film; and electrically connecting the third chip to the chip carrier by another bonding wire, thereby overcoming the drawbacks of increasing the height of the overall structure in the prior art when the second chip (i.e. a control chip) having a relatively smaller planar size than that of the first and the third chips (i.e. a memory chip) is stacked on the third chip, and further preventing short circuits occurred due to bonding wires passing over and getting in contact with the first and third chips and increasing difficulties in a wire bonding method. Moreover, since the second chip is directly mounted onto the chip carrier and the third chip is stacked stepwise on the first chip by a Film Over Wire technique to at least cover a part of the bonding wire connected the second chip by the film, thereby forming a multi-chip stack structure to save space on the chip carrier for facilitating miniaturization of electronic products.

### BRIEF DESCRIPTION OF THE DRAWINGS

FIGS. 1A and 1A (PRIOR ART) are respectively a cross-sectional view and a perspective view showing a multi-chip stack structure disclosed by U.S. Pat. No. 6,538,331.

FIGS. 2A to 2C are schematic cross-sectional views showing a multi-chip stack structure and a fabrication method thereof according to a first embodiment of the present invention; and

FIG. 3 is a schematic cross-sectional view showing a multi-chip stack structure and a fabrication method thereof according to a second embodiment of the present invention; and

FIG. 4 is a schematic cross-sectional view showing a multi-chip stack structure and a fabrication method thereof according to a third embodiment of the present invention.

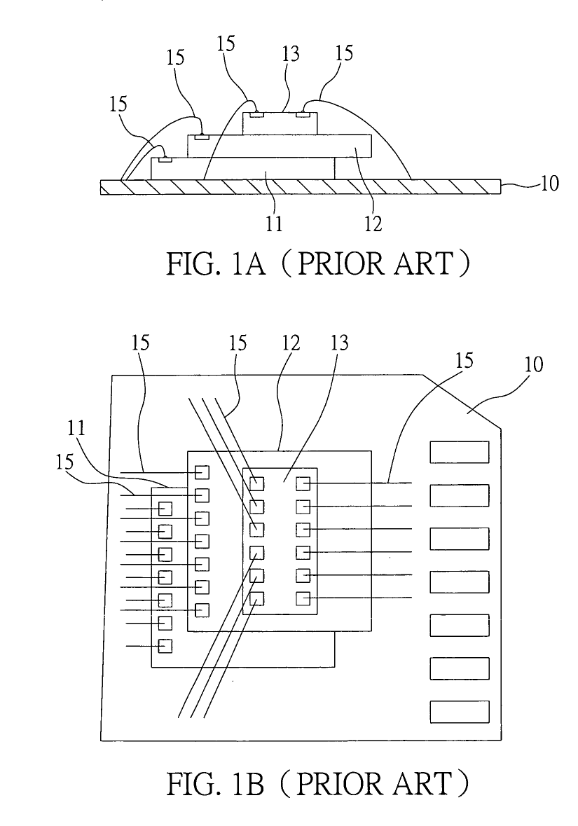

### DETAILED DESCRIPTION OF THE PREFERRED EMBODIMENTS

The following specific embodiments are provided to illustrate the present invention. Persons skilled in the art can readily gain insight into other advantages and features of the present invention based on the contents disclosed in this specification.

### First Embodiment

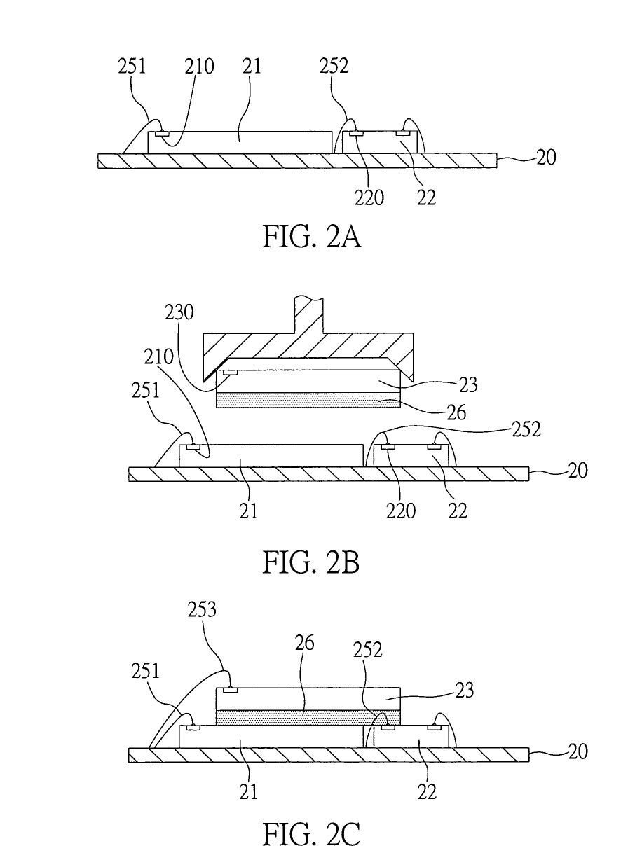

FIGS. 2A to 2C are cross-sectional views showing a multi-chip stack structure and a fabrication method thereof according to a first embodiment of the present invention. As shown in FIG. 2A, the fabricating method of the multi-chip stack structure comprises the steps of: providing a chip carrier 20 having a first surface and a second surface opposing to the first surface and at least a first chip 21 and a second chip 22 mounted on the first surface; electrically connecting the first and second chips 21, 22 to the chip carrier 20 by bonding wires 251, 252 respectively.

The first and second chips 21, 22 may be, for example, a memory chip and a control chip respectively, wherein the second chip 22 has a planar size smaller than that of the first chip 21. A plurality of bonding pads 210 are formed on an edge of a surface of the first chip 21, while a plurality of bonding pads 220 are formed on at least one edge of a surface of the second chip 22 (in this embodiment, more than one edge of the surface of the second chip 22 have a plurality of bonding pads 220 is provided). The first and second chips 21, 22 are electrically connected with the chip carrier 20 by bonding wires 251, 252 respectively. The chip carrier 20 may be a ball-grid-array (BGA) substrate, an LGA substrate or a leadframe.

As shown in FIGS. 2B and 2C, a Film over Wire (FOW) technique is employed to stack at least a third chip 23 on the first and second chips 21, 22 by a film 26 deposed between the third chip 23 and the first and second chips 21, 22, wherein the third chip 23 is stepwise stacked and mounted to the first chip 21, and the film 26 at least covers a part of the bonding wire 252 connected the second chip 22. Thereafter, the third chip 23 and the chip carrier 20 are electrically connected by a bonding wire 253.

The third chip 23 may be, for example, a memory chip having a plurality of bonding pads formed on a single edge of a surface thereof. The third chip 23 is stacked on the first chip 21 in a way that the edge having bonding pads formed thereon of the third chip 23 is horizontally deviated from the first chip 21 a predetermined distance for keeping from blocking a vertical space above the bonding pads 210 of the first chip 21, thereby allowing the first and third chips 21, 23 to be electrically connected to the chip carrier 20 by the bonding wires 251, 253 respectively in a further process.

Compared to the conventional method of simply stacking a plurality of chips, the multi-chip stack structure of the present invention are characterized by mounting at least the first chip 21 and the second chip 22 on the surface of the chip carrier 20, stacking at least the third chip 23 on the first chip 21 and the second chip 22 by a Film over Wire (FOW) technique with the film 26 deposed between the third chip 23 and the first and the second chips 21, 22, wherein the third chip 23 is stepwise stacked on the first chip 21, and at least the part of the bonding wire 252 connected to the second chip 22 is covered by the film 26, thereby forming a miniaturized package structure, facilitating the wire bonding method and also preventing short circuits due to bonding wires passing over and getting in contact with the first and third chips 21, 23.

By the fabrication method described above, the present invention further discloses a multi-chip stack structure, comprising: a chip carrier 20 having a first surface and a second surfaces opposing to the first surface; at least one first chip 21 mounted on the first surface of the chip carrier 20 and electrically connected to the chip carrier 20 by a bonding wire 251; at least one second chip 22 mounted on the first surface of the chip carrier 20 and electrically connected to the chip carrier 20 by a bonding wire 252; and at least one third chip 23 stacked on the first and second chips 21, 22 by a film 26 deposed therebetween, and connected to the chip carrier 20 by a bonding wire 253, wherein the third chip 23 is mounted on the first chip 21 stepwise and at least a part of the bonding wire 252 connected to the second chip 22 is covered by the film 26.

Accordingly, the multi-chip stack structure and the fabrication method thereof according to the present invention are characterized by mounting at least a first and a second chips on the surface of the chip carrier, electrically connecting the first and second chips to the chip carrier by a plurality of bonding wires; stacking the third chip stepwise on the first and second chips by a Film over Wire (FOW technique), wherein the third chip is stepwise stacked on the first chip, and at least a part of the bonding wire connected to the second chip is covered by the film; and electrically connecting the chips to the chip carrier by another bonding wire, thereby overcoming the drawbacks of increasing the height of the overall structure in the prior art when the second chip (i.e. a control chip) having a relatively smaller planar size than that of the first and the third chips (i.e. a memory chip) is stacked on the third chip, and further preventing short circuits occurred due to bonding wires passing over and getting in contact with the first and third chips and increasing difficulties in a wire bonding method. Moreover, since the second chip is directly mounted onto the chip carrier and the third chip is stacked stepwise on the first chip by a Film Over Wire technique to at least cover a part of the bonding wire connected the second chip by the film, thereby forming a multi-chip stack structure to save space on the chip carrier for facilitating miniaturization of electronic products.

### Second Embodiment

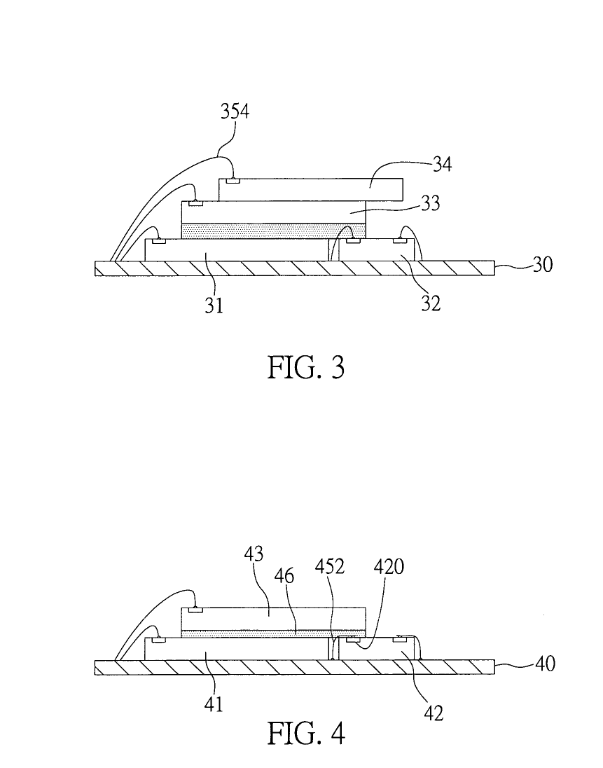

FIG. 3 schematically illustrates a multi-chip stack structure and a fabrication method thereof according to a second embodiment of the present invention. This embodiment is substantially the same as the first embodiment and mainly different from the first embodiment in that a fourth chip 34, such as a memory chip, is further stacked stepwise on a third chip 33, which is mounted and stacked on first and second chips 31, 32, and electrically connected to a chip carrier 30 by a bonding wire 354 to increase the memory size in the structure.

### Third Embodiment

FIG. 4 schematically illustrates a multi-chip stack structure and a fabrication method thereof according to a third embodiment of the present invention. This embodiment is substantially the same as the first embodiment and mainly different from the first embodiment in that a second chip 42 having a bond pad 420 is electrically connected to a chip carrier 40 by a bonding wire 452 through a reverse wire bonding method, that is, an outer end of the bonding wire 452 adapted to connect the second chip 42 and the chip carrier 40 is bonded to the bonding pad 420 of the second chip 42 to form a protruding stud. Thereafter, the chip carrier 40 is welded and guided upwardly to be welded to the protruding stud, such that the inner end of the bonding wire 452 can be connected by a stitch bond method to the protruding stud formed on the bonding pad 420 of the second chip 42, thereby decreasing the height of the loop electrically connecting the second chip 42 to the chip carrier 40, and further reducing the thickness of the film 46 to be disposed on a first chip 41 and the second chips 42 which in turn reduces the height of the overall stack structure as a result.

Furthermore, the first chip 41 and a third chip 43 can be electrically connected to the chip carrier 40 by bonding wires through either a common wire bonding method or a reverse wire bond method.

The aforesaid embodiments merely serve as the preferred embodiments of the present invention. The aforesaid embodiments should not be construed as to limit the scope of the present invention in any way. Hence, many other changes can actually be made in the present invention. It will be apparent to those skilled in the art that all equivalent modifications or changes made to the present invention, without departing from the spirit and the technical concepts disclosed by the present invention, should fall within the scope of the appended claims.

What is claimed is:

1. A fabricating method of a multi-chip stack structure, comprising steps of:
providing a chip carrier having a first surface and a second surface opposing thereto and at least a first chip and a second chip deposed on the first surface, wherein the first and second chips are electrically connected with the chip carrier by a plurality of bonding wires;
stacking at least a third chip on the first and second chips by a film deposed therebetween, wherein the third chip is stacked stepwise on the first chip, and a part of the bonding wire connected to the second chip is covered by the film; and
electrically connecting the third chip and the chip carrier by another bonding wire.

2. The fabrication method of claim 1, wherein a planar size of the second chip is smaller than that of the first chip.

3. The fabrication method of claim 1, wherein the first and third chips are memory chips and the second chip is a control chip.

4. The fabrication method of claim 3, wherein the first and third chips each has a plurality of bonding pads formed on a single edge of a surface thereof, while the second chip has a plurality of bonding pads formed on at least an edge of a surface thereof.

5. The fabrication method of claim 1, wherein the chip carrier is one selected from a group consisting of a Ball Grid Array (BGA) substrate, a Land Grid Array (LGA) substrate and a leadframe.

6. The fabrication method of claim 1, wherein the step of stacking at least a third chip on the first and second chips is performed by a Film over Wire technique.

7. The fabrication method of claim 1, further comprising a step of:
stacking a fourth chip on the third chip stepwise.

8. The fabrication method of claim 1, wherein each of the first, second and third chips is electrically connected to the chip carrier by the bonding wires respectively by one of a wire bonding method and a reverse wire bond method.

9. A multi-chip stack structure, comprising:
a chip carrier having a first surface and a second surface opposing thereto;
at least one first chip mounted on the first surface of the chip carrier and electrically connected to the chip carrier by a first bonding wire;
at least one second chip mounted on the first surface of the chip carrier and electrically connected to the chip carrier by a second bonding wire; and
at least one third chip stacked on the first and second chips by a film deposed therebetween and electrically connected to the chip carrier by a third bonding wire, wherein at least a part of the second bonding wire connected to the second chip is covered by the film and the third chip is stepwise stacked on the first chip.

10. The multi-chip stack structure of claim 9, wherein a planar size of the second chip is smaller than that of the first chip.

11. The multi-chip stack structure of claim 9, wherein the first and third chips are memory chips and the second chip is a control chip.

12. The multi-chip stack structure of claim 9, wherein the first and third chips each has a plurality of bonding pads formed on a shingle edge of a surface thereof, and the second chip has a plurality of bonding pads formed on at least an edge of a surface thereof.

13. The multi-chip stack structure of claim 9, wherein the chip carrier is one selected from a group consisting of a Ball Grid Array (BGA) substrate, a Land Grid Array (LGA) substrate and a leadframe.

14. The multi-chip stack structure of claim 9, wherein the third chip is stacked on the first and second chips by a Film over Wire technique.

15. The multi-chip stack structure of claim 9, further comprising a fourth chip stepwise stacked on the third chip.

16. The multi-chip stack structure of claim 9, wherein each of the first, second and third chips is electrically connected to the chip carrier by the bonding wires respectively by one of a wire bonding method and a reverse wire bond method.
